(19) United States
(12) Patent Application Publication
(10) Pub. No.: US 2015/0206965 A1
(43) Pub. Date: Jul. 23, 2015

(54) HIGH PERFORMANCE FINFET

(71) Applicant: Altera Corporation, San Jose, CA (US)

(72) Inventors: Ning Cheng, San Jose, CA (US); Peter J. McElheny, Morgan Hill, CA (US)

(73) Assignee: Altera Corporation, San Jose, CA (US)

(21) Appl. No.: 14/222,629

(22) Filed: Mar. 22, 2014

Related U.S. Application Data
(63) Continuation-in-part of application No. 14/080,387, filed on Nov. 14, 2013.

(51) Int. Cl. H01L 29/78; H01L 21/8238

(52) U.S. Cl. CPC H01L 29/785; H01L 21/823821

(57) ABSTRACT

A FinFET is described having first, second, and third pluralities of fins with gate structures and source and drain regions formed on the fins so that PMOS transistors are formed on the first plurality of fins, NMOS transistors are formed on the second plurality and PMOS transistors are formed on the third plurality. In one embodiment, the first and second pluralities of fins are made of strained silicon; and the third plurality of fins is made of a material such as germanium or silicon germanium that has a higher hole mobility than strained silicon. In a second embodiment, the first plurality of fins is made of silicon, the second plurality of strained silicon, germanium or a III-V compound; and the third plurality is made of germanium or silicon germanium.

### BACKGROUND

This application is a continuation-in-part of application Ser. No. 14/080,387, filed Nov. 14, 2013, which application is incorporated by reference herein in its entirety.

This relates to semiconductor devices such as FinFETs (Fin Field Effect Transistors) (a/k/a tri-gate transistors).

A conventional field effect transistor (FET) is an essentially planar device having a gate structure that extends across the surface of a semiconductor such as monocrystalline silicon and doped source and drain regions in the semiconductor on either side of the gate. The gate is insulated from the semiconductor by a thin layer of an insulator such as silicon oxide. A voltage applied to the gate controls current flow in an un-doped channel that extends between the doped source and drain regions in the semiconductor beneath the gate.

The switching speed of the FET depends on the amount of current flow between the source and drain regions. Current flow depends on the width of the gate where width is the direction in the channel that is perpendicular to the direction of current flow. With the continuing demand for higher speed transistors for use in communication and computer equipment, there is a continuing interest in making transistor devices with wider gates.

FinFETs have been developed to obtain larger gate widths. A fin is a thin segment of semiconductor material standing on edge, thereby making available multiple surfaces for the formation of gate structures. The fins have first and second major surfaces that are opposite one another and usually are symmetric about a center plane that bisects the fin lengthwise. The major surfaces are often illustrated as being parallel as in U.S. Pat. No. 7,612,405 B2 or Pub. No. US2008/0128797 A1, which are incorporated herein by reference; but process limitations usually result in surfaces that slope outwardly from top to bottom of the fin with the result that the cross-section of the fin is trapezoidal in shape. In some cases, the two major surfaces meet at the top. In some embodiments, a separate gate structure may be located on each surface of each fin. In other embodiments, there is a common gate structure for all surfaces.

Doped source and drain regions are located on opposite sides of the gates. As in a planar FET, a voltage applied to the gate controls current flow in an un-doped channel that extends between the doped source and drain regions in the semiconductor beneath the gate.

Further details on FinFETs may be found at pages 137-138 of N. H. E. Weste and D. Harris, CMOS VLSI Design (Pearson, 3^{rd} ed., 2005) which are incorporated herein by reference.

Despite the increased speed that is available from silicon FinFETs, there is a need for still faster operations. This is achieved by using in the fins strained silicon instead of silicon for NMOS devices and germanium or silicon germanium (SiGe) for PMOS devices. However, germanium and SiGe have smaller bandgaps than silicon with the result that PMOS devices formed of these materials have significantly higher leakage currents (Iboff). High leakage currents not only increase static leakage but also produce excessive heating of the semiconductor chip in which the PMOS transistors are formed. This is especially troublesome in circuits where large numbers of PMOS transistors are used such as static random access memory (SRAM) circuits.

### SUMMARY

The present invention is an integrated circuit that reduces power loss in FinFETs and a method for manufacturing such a circuit.

An illustrative FinFET of the present invention comprises first, second, and third pluralities of fins having gate structures and source and drain regions formed on the fins so that PMOS transistors are formed on the first plurality of fins, NMOS transistors are formed on the second plurality of fins and PMOS transistors are formed on the third plurality of fins. In one embodiment, the first and second pluralities of fins are made of strained silicon; and the third plurality of fins is made of a material such as germanium or silicon germanium that has a higher hole mobility than strained silicon. In a second embodiment, the first plurality of fins is made of silicon, the second plurality of strained silicon, germanium or a III-V compound; and the third plurality is made of a material such as germanium or silicon germanium that has a higher hole mobility than strained silicon.

There are numerous ways to form the fins of a FinFET. Illustratively, transistors are formed on the fins by forming the gate structure on the fins and then using ion implantation of N-type dopants to form the source and drain regions of the NMOS transistors and ion implantation of P-type dopants to form the source and drain regions of the PMOS transistors.

We have found that the PMOS transistors formed on strained silicon fins have leakage currents that are as low as, or even lower than, one-fifteenth ( 1/15) the leakage current of a similar PMOS transistor formed on a germanium or SiGe fin. One application for such PMOS transistors is in static RAM cells such as those that are used to store the configuration bits that program the logic elements and switching circuitry of field programmable gate arrays (FPGAS). In current technologies, such configuration memories may include millions of static RAM cells.

Numerous variations may be practiced in the preferred embodiment.

### BRIEF DESCRIPTION OF THE DRAWINGS

These and other objects and advantages of the present invention will be apparent to those of ordinary skill in the art in view of the following detailed description in which:

FIG. 1 is a perspective view of a first illustrative embodiment of the invention;

FIG. 2 is a perspective view of a second illustrative embodiment of the invention;

FIG. 3 is a schematic diagram depicting a field programmable gate array and its configuration memory;

FIG. 4 is a flow chart depicting an illustrative embodiment of the method of the invention; and

FIG. 5 is a plot depicting the electron and hole mobility of various semiconductor materials.

### DETAILED DESCRIPTION

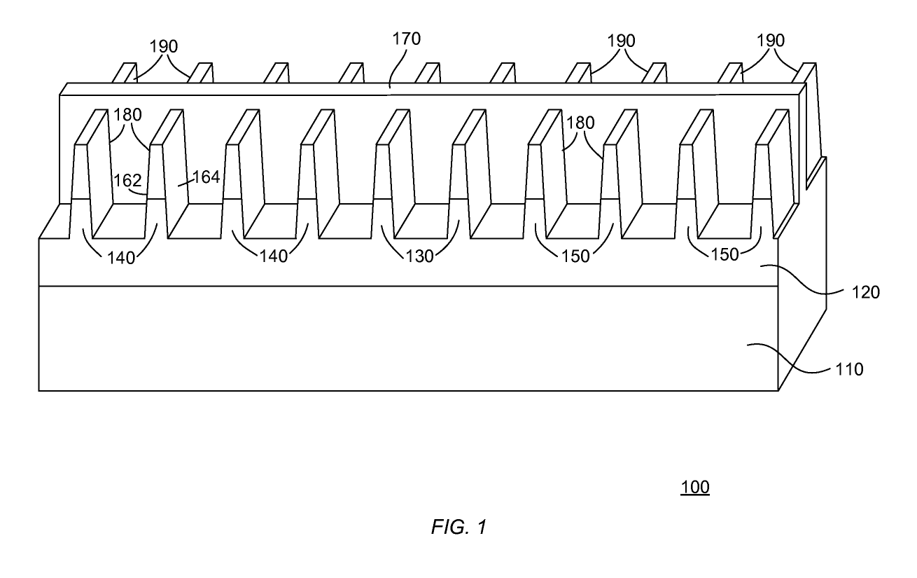

FIG. 1 is a cross-section of a first illustrative embodiment of a FinFET 100 of the invention. FinFET 100 comprises a silicon substrate 110, a silicon germanium strain relaxed barrier 120 formed on silicon substrate 110, a first plurality of fins 130 of strained silicon formed on strain relaxed barrier 120, a second plurality of fins 140 of strained silicon formed on strain relaxed barrier 120, and a third plurality of fins 150 made of a semiconductor material having a hole mobility that is greater than that of strained silicon and is formed on strain relaxed barrier 120. Illustratively, the semiconductor material is germanium or silicon germanium. Each of the fins has two major surfaces 162, 164. Gate structures 170 and source and drain regions 180, 190 are formed on the surfaces of fins 130, 140 and 150 so that PMOS transistors are formed on fins 130, NMOS transistors are formed on fins 140 and PMOS transistors are formed on fins 150.

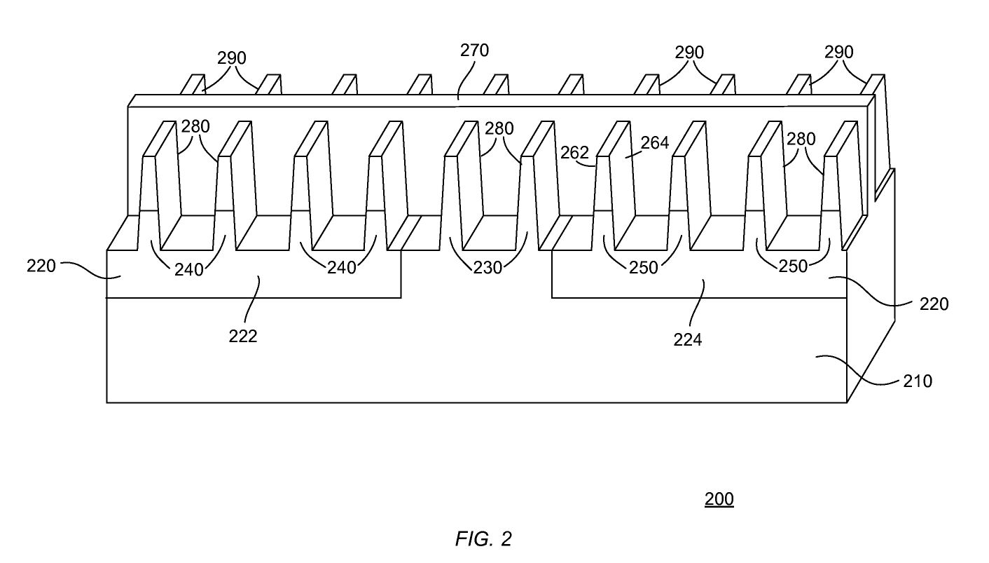

FIG. 2 is a cross-section of a second illustrative embodiment of a FinFET 200 of the invention. FinFET 200 comprises a silicon substrate 210, a strain relaxed barrier 220 formed on portions of substrate 210, a first plurality of fins 230 of silicon formed on substrate 210, a second plurality of fins 240 of strained silicon, germanium or a III-V compound such as InGaAs formed on a first portion 222 of a strain relaxed barrier 220, and a third plurality of fins 250 made of a semiconductor material having a hole mobility that is greater than that of strained silicon and is formed on a second portion 224 of strain relaxed barrier 220. Illustratively, the semiconductor material is germanium or silicon germanium. Each of the fins has two major surfaces 262, 264. Gate structures 270 and source and drain regions 280, 290 are formed on the surfaces of the fins 230, 240 and 250 so that PMOS transistors are formed on fins 230, NMOS transistors are formed on fins 240 and PMOS transistors are formed on fins 250.

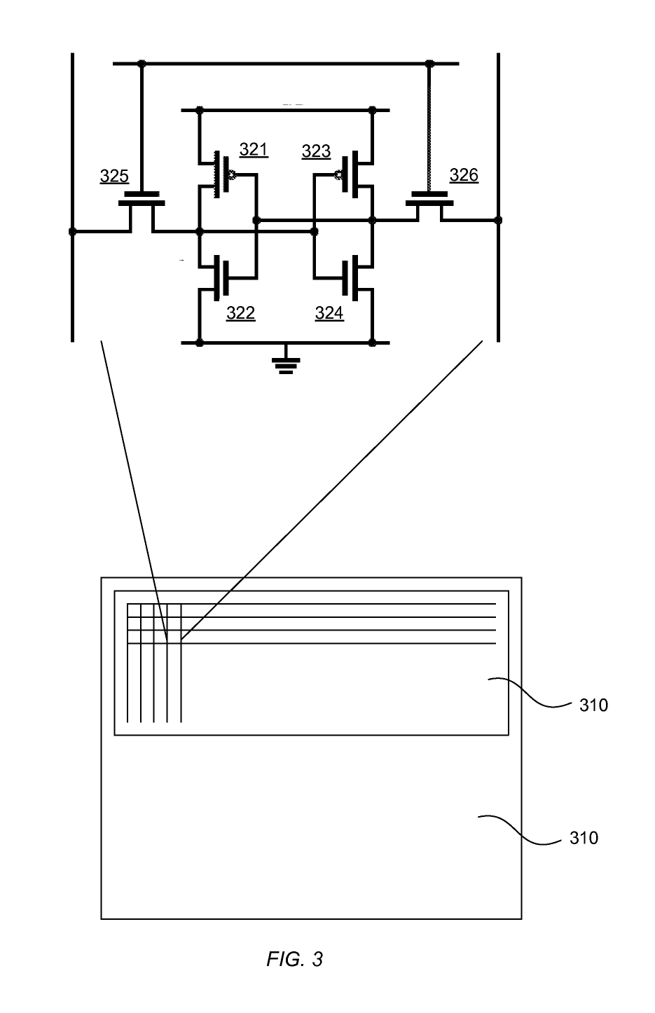

We have found that the PMOS transistors formed on strained silicon fins have leakage currents that are as low as, or even lower than, one-fifteenth ( 1/15) the leakage current of similar PMOS transistors formed on a germanium or SiGe fin. One application for such PMOS transistors is in the six transistor static RAM cells that are used, for example, to store the configuration bits that configure FPGAs. FIG. 3 is a schematic diagram depicting an FPGA 300, its configuration RAM 310 and one cell 320 of the configuration RAM. As shown in FIG. 3, the cell comprises a latch having a first pair of series-connected PMOS and NMOS transistors 321, 322 cross-coupled with a second pair of series-connected PMOS and NMOS transistors 323, 324 and NMOS pass transistors 325, 326 for connecting the latch to the bit lines bit and bit b. Since a configuration RAM in present day technologies may include millions of static RAM cells, a substantial reduction in the leakage current of the PMOS transistors used in such cells is of great value. For some FPGA products, static power requirements are reduced up to about thirty percent (30%); and total power requirements are reduced up to about ten percent (10%).

Advantageously, the NMOS transistors of the FinFETs of the present invention may be used as the NMOS transistors in the static RAM cells of configuration RAM 310.

There are numerous ways to form the fins of a FinFET. In several of these, the fins are formed from a block of material using conventional photolithographic processes to remove unwanted material and leave the final shape of a plurality of fins standing on edge on a substrate. Often the substrate is a wafer of semiconductor material such as silicon; and in today's technology the wafer may be up to 12 inches (300 millimeters) in diameter.

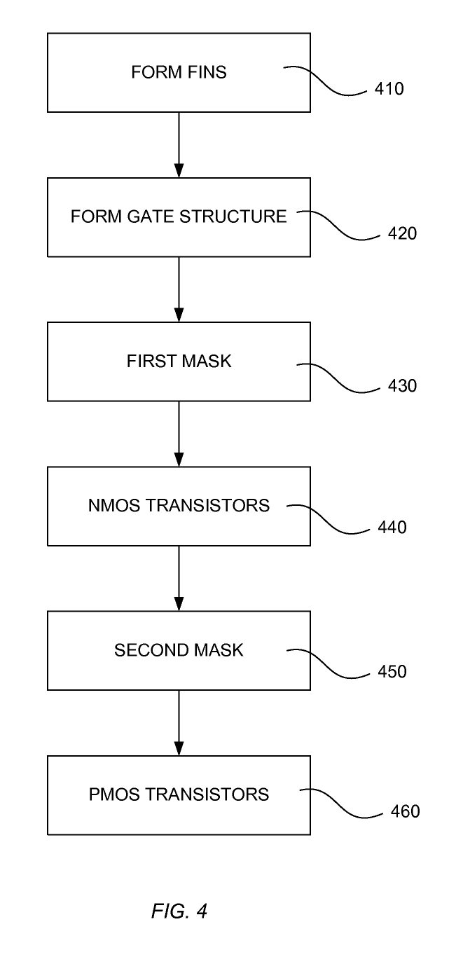

FIG. 4 is a flowchart for making the FinFET transistors shown in FIG. 1. The process begins at step 410 with the formation of a plurality of fins on a silicon germanium strain relaxed barrier on a silicon substrate. Steps for making such a structure are known in the art. At step 420, a gate structure is formed that extends across the fins in a direction substantially perpendicular to the ridges and valleys of the fins. Processes for forming such a gate structure are well known. At step 430, a first mask is formed over the portion of the FinFET where the PMOS transistors 130 and 150 are to be located. NMOS transistors 140 are then formed at step 440 by ion implantation of N-type dopants such as arsenic to form N-type source and drain regions on the major surfaces of the fins on the sides of the gate that are not protected by the first mask. The first mask is then removed and a second mask is formed at step 450 over the portion of the FinFET where the N-type source and drain regions were just formed. PMOS transistors 130, 150 are then formed at step 460 by ion implantation of P-type dopants such as boron to form P-type source and drain regions on the major surfaces of the fins on the sides of the gate that are not protected by the second mask. The second mask is then removed.

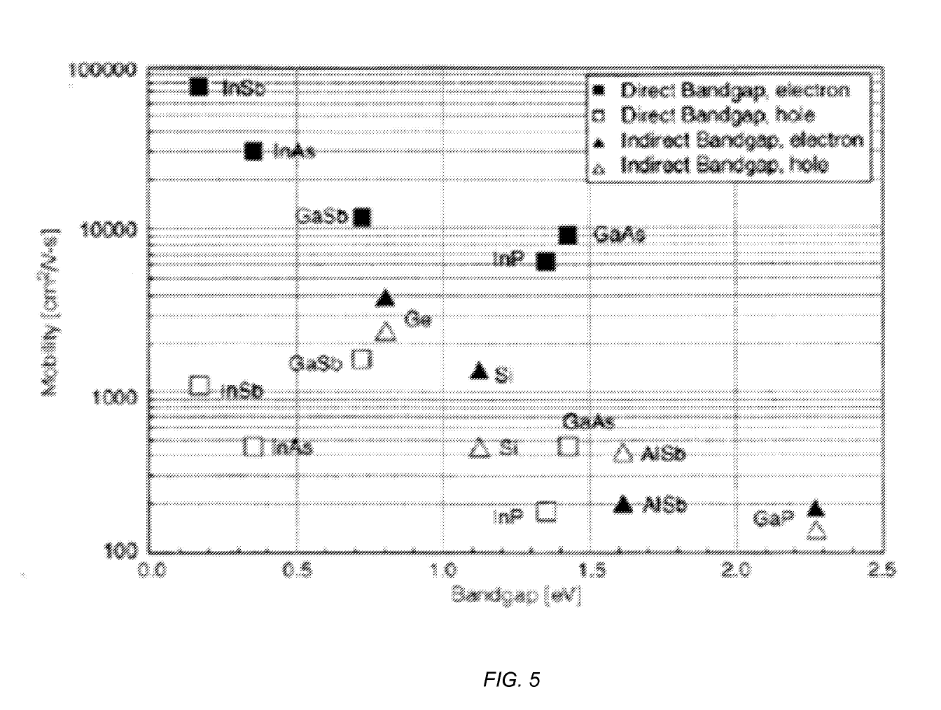

As will be apparent to those skilled in the art, numerous variations may be practiced within the spirit and scope of the present invention. For example, numerous semiconductor materials may be used in the practice of the invention. FIG. 5 is a chart depicting the electron and hole mobilities versus bandgap for silicon, germanium and a variety of III-V compounds. These materials include compounds such as gallium antimonide (GaSb) and indium antimonide (InSb) that have hole mobilities greater than that of silicon that may be used in the practice of the invention. These materials also include compounds such as GaSb, InSb, indium arsenide (InAs) and indium gallium arsenide (InGaAs) that have electron mobilities greater than that of silicon that may be used in the practice of the invention. Many other III-V compounds not identified on the chart but well known in the art may also be used. While one process has been described for the formation of the FinFETs, other processes may also be used; and numerous variations in these processes may also be practiced. Different materials may be used as cap layers, mask layers and the like; and a wide variety of etchants and etching processes may be used to remove these materials.

1. A FinFET comprising:
at least a first fin having first and second opposing major surfaces and being made of a first semiconductor material;
at least a first PMOS transistor formed on the first and second major surfaces of the first fin;
at least a second fin having third and fourth opposing major surfaces and being made of the first semiconductor material;
at least a first NMOS transistor formed on the third and fourth major surfaces of the second fin;
at least a third fin having fifth and sixth major surfaces and being made of a second semiconductor material having a hole mobility that is greater than that of strained silicon. and
at least a second PMOS transistor formed on the fifth and sixth major surfaces of the third fin.

2. The FinFET of claim 1 wherein the first semiconductor material is strained silicon.

3. The FinFET of claim 2 wherein the first, second and third fins are formed on a silicon germanium strain relaxed barrier that is formed on a silicon substrate.

4. The FinFET of claim 2 wherein the semiconductor material having a hole mobility greater than that of strained silicon is germanium or silicon germanium.

5. The FinFET of claim 2 wherein the semiconductor material having an hole mobility greater than that of strained silicon is, a III-V compound.

6. The Fin FET of claim 5 wherein the III-V compound is indium antimonide or gallium antimonide.

7. The FinFET of claim 1 wherein the first and second opposing major surfaces are substantially parallel, the third and fourth opposing major surfaces are substantially parallel, and the fifth and sixth opposing major surfaces are substantially parallel.

8. The FinFET of claim 1 comprising a plurality of first fins, a plurality of second fins, and a plurality of third fins.

9. A FinFET comprising:
a silicon substrate;
at least a first fin of silicon formed on the silicon substrate, said fin having first and second opposing major surfaces;
at least a first MOS transistor formed on the first and second major surfaces of the first fin;
a silicon germanium strain relaxed barrier formed on the silicon substrate where the first fin is not formed;
at least a second fin formed on the strain relaxed barrier, said second fin having third and fourth opposing major surfaces and being made of a first semiconductor material having an electron mobility greater than that of silicon;
at least one NMOS transistor formed on the third and fourth major surfaces of the second fin;
at least a third fin formed on the strain relaxed barrier said third fin having fifth and sixth opposing major surfaces and being made of a second semiconductor material having a hole mobility that is greater than that of silicon. and
at least one PMOS transistor formed on the fifth and sixth major surfaces of the third fin.

10. The FinFET of claim 9 wherein the first semiconductor material having an electron mobility greater than that of strained silicon is germanium, silicon germanium, or a III-V compound.

11. The FinFET of claim 9 wherein the second semiconductor material having an hole mobility greater than that of silicon is, germanium, silicon germanium, or a III-V compound.

12. The FinFET of claim 9 wherein the first MOS transistor is a PMOS transistor.

13. The FinFET of claim 9 wherein the first MOS transistor is a NMOS transistor.

14. The FINFET of claim 9 comprising a plurality of first fins, a plurality of second fins, and a plurality of third fins.

15. (canceled)

16. (canceled)

17. (canceled)

18. (canceled)

19. (canceled)

20. (canceled)

21. A FinFET structure comprising:
a first plurality of thin segments of a first semiconductor material each segment having first and second opposing major surfaces;
a second plurality of thin segments of a second semiconductor material, each segment having third and fourth opposing major surfaces;
some of the first plurality of thin segments of the first semiconductor material having a first conductivity type;
the second plurality of thin segments of the second semiconductor material having a second conductivity type;
at least one thin segment of the first plurality of thin segments of the first semiconductor material having the second conductivity type; and
gates on the thin segments.

22. The FinFET of claim 21 wherein the first semiconductor material is strained silicon.

23. The FinFET of claim 22 wherein the thin segments are formed on a silicon germanium strain relaxed barrier that is formed on a silicon substrate.

24. The FinFET of claim 22 wherein the second semiconductor material is germanium, silicon germanium, or a III-V compound.

25. The Fin FET of claim 24 wherein the compound is indium antimonide or gallium antimonide.

26. The FinFET of claim 21 wherein the first and second opposing major surfaces are substantially parallel and the third and fourth opposing major surfaces are substantially parallel.
